(19) United States
(12) Patent Application Publication
(10) Pub. No.: US 2015/0083206 A1
(43) Pub. Date: Mar. 26, 2015

(54) PHOTOVOLTAIC CELLS

(71) Applicant: The University of Manchester, Manchester (GB)

(72) Inventors: Konstantin Novoselov, Manchester (GB); Liam Britnell, Manchester (GB)

(73) Assignee: THE UNIVERSITY OF MANCHESTER, Manchester (GB)

(21) Appl. No.: 14/387,083

(22) PCT Filed: Mar. 22, 2013
(86) PCT No.: PCT/GB2013/050753

§ 371 Date: Sep. 22, 2014

(30) Foreign Application Priority Data
Mar. 22, 2012 (GB) 1205082.9
Sep. 17, 2012 (GB) 1216536.1

(51) Int. Cl. H01L 31/0352; H01L 31/18; H01L 31/0224

(52) U.S. Cl. CPC H01L 31/035209; H01L 31/022433; H01L 31/186; H01L 31/18
USPC 136/256; 136/258; 438/94

(57) ABSTRACT

This invention relates to cells and devices for harvesting light. Specifically the cell comprises at least one electrode which comprises graphene or modified graphene and layer of a transition metal dichalcogenide in a vertical heterostructure. The cell may be part of a light harvesting device. The invention also relates to materials and methods for making such cells and devices.

This invention relates to cells and devices for harvesting light. Specifically the cell comprises at least one electrode which comprises graphene or modified graphene and layer of a transition metal dichalcogenide in a vertical heterostructure. The cell may be part of a light harvesting device. The invention also relates to materials and methods for making such cells and devices.

### BACKGROUND

Graphene is a two-dimensional allotrope of carbon, in which a planar sheet of sp² hybridised carbon atoms is arranged in a ‘honeycomb pattern’ of tessellated hexagons. Essentially graphene is a single layer of graphite. Graphene is a semi metal with high room temperature charge carrier mobility. It is stable in ambient conditions and its electronic properties can be controlled through application of an electric field as with traditional silicon transistors (K. S, Novoselov, A. K. Geim, S. V. Morozov, D. Jiang, Y. Zhang, S. V. Dubonos, I.V. Grigorieva and A. A. Firsov, “Electric field Effect in Atomically Thin Carbon Films” Science, Vol. 306, No. 5696, pp. 666-669, 2004.).

The advent of graphene and subsequent discovery of its multitude of superior properties, has led to the identification of many other two-dimensional crystals through both chemical modification of graphene and exfoliation of other layered compounds. Other two dimensional materials which have been isolated include NbSe₂, bismuth strontium calcium copper oxide (BSCCO) and MoS₂. These are also stable and can exhibit complementary electronic properties to graphene, such as being insulators, semiconductors or superconductors.

Graphene's properties are typically encumbered by its proximity to most substrates. Although it is possible to suspend graphene, this is technologically unfavourable due to the fragile nature of these devices. However, boron nitride (BN; a two-dimensional layered material which is a good insulator) provides a good substrate which has a much smaller effect on graphene's properties than previously reported materials. This is manifest in the increase in electron mobility and decrease in charge inhomogeneity of graphene. It has also become possible to achieve very clean and precise transfer of thin crystal flakes to the surfaces of one another and devices can be prepared which involve two electrically isolated graphene layers.

This new area of research and progress in precise transferring of the crystals whilst maintaining their quality has resulted in the emergence of a new class of materials: two-dimensional-crystal based heterostructures. More specifically, there is the possibility to create hybrid materials, by stacking combinations of two-dimensional crystals with differing properties. These structures are interesting from both a fundamental and an application based point of view. It has, for instance, been shown that a trilayer stack of graphene/boron nitride/graphene is operable as a tunnelling transistor. This means that the size of the barrier for electrons (BN) to flow between the two separate graphene layers can be varied by a gate electrode. These tunnelling devices are intrinsically fast and may be suitable for high frequency applications. The on/off ratio was enhanced by replacing the boron nitride layer with that of a material with a smaller band gap such as MoS₂.

As well as allowing the operation of tunnelling transistors, this layering of sheets of graphene and boron nitride or molybdenum disulfide has permitted the observation of phenomena such as Coulomb drag. Coulomb drag is where the flow of electrons in one graphene layer of the graphene/BN/graphene heterostructures were observed to ‘drag’ along electrons in the other layer. These effects have previously been seen in GaAlAs heterostructures but important here is the ability to make the separation so small that electrons are closer to their counterparts in the other layer than within their own layer. There is also the possibility to tune between electrons and holes, which is not possible in conventional semiconductors.

Graphene can now be synthesised and transferred onto a substrate with roll-to-roll processing, enabling the possibility of industrial production of devices such as touch screens (S Bae, H. Kim, X. Xu. J.-S. Park, Y. Zheng, J. Balakrishnan, T. Lei, H. R. Kim, Y. I. Song, Y.-J. Kim, K. S, Kim, B. Öozyilmaz, J.-H. Ahn, S. Ijima Roll-to-roll production of 30-inch graphene films for transparent electrodes; Nature Nanotechnology, 5, 574-578, 2010).

Graphene is also intrinsically very strong. It has been found to be one of the strongest materials ever measured. This means that graphene is inherently able to withstand large deformation forces. Combined with graphene's ability to elastically stretch up to 20% this makes it suitable for flexible electronic applications.

Transition metal dichalcogenides (TMDCs) are a group of layered materials that have been found to exfoliate to monolayer by both mechanical and chemical methods. Many of these various materials—MoS₂, WS₂, TaS₂ to name a few—are structurally similar but have an array of electronic properties ranging from semiconducting to metallic depending on their exact composition and thickness. Tungsten disulfide (WS₂) has various applications including solid state lubrication and industrial surface protection.

Photovoltaic cells harvest solar (light) energy and convert it to electrical energy. They work using the photovoltaic effect, in which light energy (photons) excites electrons into a higher energy state. In suitable materials, this generates electron holes and free electrons which, providing a potential difference is applied across the material, flow as current. Photovoltaic cells are a renewable source of energy which produces around 80 billion kWh of electricity worldwide. Materials presently used for photovoltaic cells include monocrystalline silicon, polycrystalline silicon, amorphous silicon, cadmium telluride, and copper indium gallium selenide/sulfide.

Photovoltaic cells are known which use graphene as an electrode (see for example, WO 2011/129708). These cells are based, however, on existing technologies in which the photoactive layer or layers are substantially thicker than the photoactive layers used in the present invention.

For both MoS₂ and WS₂ photocurrent peaks in the visible part of the spectrum and is roughly constant over the range 450-650 nm. Previously, WS₂ structures have been studied for solar harvesting (C. Baillif, M. Regula, P. E. Schmidt, M. Rem\check{s}kar, R. Sanjinés, F. Lévy Preparation and characterisation of highly oriented, photoconducting WS₂ thin films; Appl. Phys. A, 62, 543-546, 1996.). However, efforts to extract photocurrent have been hampered by the need to create a PN junction to separate the electron-hole (e-h) pairs, created by incoming photons.

It is an aim of embodiments of the present invention to provide a flexible photovoltaic cell.

It is a further aim of embodiments of the invention to provide a photovoltaic cell or light-harvesting device which converts a higher percentage of the light energy (e.g. solar light energy) incident upon it into electricity than those of the prior art. In other words it is an aim to provide a cell or device which has a higher energy conversion efficiency than those of the prior art.

It is a further aim of embodiments of the invention to provide a photovoltaic cell or light-harvesting device which is cheaper to manufacture than those of the prior art.

Yet another aim is to provide a photovoltaic cell which is has a greater longevity than those of the prior art.

Embodiments of the following invention may achieve at least one of the above aims.

### BRIEF SUMMARY OF THE DISCLOSURE

In accordance with a first aspect of the invention, there is provided a photovoltaic cell or device comprising a two-dimensional graphene heterostructure.

In accordance with a second aspect of the invention, there is provided the use of a two dimensional graphene heterostructure in a photovoltaic cell or device.

In an embodiment, the graphene heterostructure comprises two graphene two-dimensional crystals within tunnelling proximity of each other.

In an embodiment, the cell or device further comprises a means of creating an electric field between the graphene crystals.

In an embodiment, the means of creating an electric field is a means of applying a bias voltage.

In an embodiment, the means of creating an electric field is using the proximity effect of other metallic two-dimensional crystals.

In an embodiment, the two graphene crystals are separated by layers of BN.

In an embodiment, the heterostructure further comprises a transition metal dichalcogenide.

In an embodiment, the heterostructure is used in combination with plasmonic nanostructures. In a further embodiment, the nanostructures are golden dots.

In accordance with a third aspect of the present invention, there is provided a photovoltaic cell in which the light harvesting portion comprises at least the following layers:
a first electrode layer which comprises graphene or modified graphene (e.g. doped graphene);
one or more layers comprising a transition metal dichalcogenide; and
a second electrode layer;
   wherein the layers are stacked sequentially to form a laminate structure and the or each layer of transition metal dichalcogenide is situated between the first and the second electrode layer and the or each transition metal dichalcogenide layer is in electrical contact with both electrodes.

It may be that the first electrode layer, the TMDC layer and the second electrode layer each comprise one or more two-dimensional crystals. Thus, a photovoltaic cell of the first aspect may be a photovoltaic cell of the third aspect and the photovoltaic device of the first aspect may comprise one or more (e.g. a plurality of) photovoltaic cells of the third aspect.

The first electrode layer is that which is closest to the light source in use (e.g. it is the layer which faces the sun). It is the layer through which the light must pass to reach the photoactive transition metal dichalcogenide layer. Usually, in use, the first electrode layer will be the top layer and the second electrode layer will be the bottom layer.

In an embodiment, the first electrode layer comprises graphene. In an alternative embodiment, the first electrode layer comprises modified graphene (e.g. doped graphene). Graphene is both an excellent conductor and is substantially transparent to actinic radiation, e.g. visible and near visible light. Graphene is also very flexible. Many of its derivatives (e.g. doped graphene) retain these properties. Graphene also has a variable work function which can be changed easily using electrostatic gating.

Thus, in an embodiment, the first electrode layer is formed from one or more two-dimensional crystals of graphene. Alternatively, the first electrode layer is formed from one or more two-dimensional crystals of modified graphene (e.g. doped graphene).

In an embodiment, the second electrode layer comprises graphene or modified graphene (e.g. doped graphene). In a further embodiment, the second electrode layer comprises graphene. In an alternative embodiment, the second electrode layer comprises modified graphene (e.g. doped graphene). In a further alternative, the second electrode layer comprises a metal.

Thus, in an embodiment, the second electrode layer is formed from one or more two-dimensional crystals of graphene. Alternatively, the second electrode layer is formed from one or more two-dimensional crystals of modified graphene (e.g. doped graphene).

In an embodiment, the first and second electrodes are both formed from graphene or modified graphene and the two graphene layers each have a different work function. The different work function may be induced using differential modification (e.g. differential doping) of graphene and/or by using a gate electrode.

In an embodiment, the first and second electrode layers are formed of different materials. As well as having its usual meaning, the term ‘different materials’ is intended to include differentially doped graphene (including the case where one electrode layer is formed from graphene and the other is formed from a doped graphene).

Where the two electrode layers are made from different materials, this leads to a potential difference between the electrodes which allows the electron holes and/or free electrons induced in the transition metal dichalcogenide to flow as current. Thus, it may be that the first and second electrode layers do not both comprise graphene. In an embodiment, the first electrode layer comprises graphene and the second electrode layer comprises modified graphene (e.g. doped graphene). In an alternative embodiment, the first electrode layer comprises modified graphene (e.g. doped graphene) and the second electrode layer comprises graphene.

In an embodiment, the first electrode layer is formed from one or more two-dimensional crystals of graphene and the second electrode layer is formed from one or more two-dimensional crystals of modified graphene (e.g. doped graphene). In an alternative embodiment, the first electrode layer is formed from one or more two-dimensional crystals of modified graphene (e.g. doped graphene) and the second electrode layer is formed from one or more two-dimensional crystals of graphene.

In an embodiment, the first electrode layer comprises graphene and the second electrode layer comprises graphene which has been doped with a dopant which changes the work function of graphene. In an embodiment, the second electrode layer comprises graphene and the first electrode layer comprises graphene which has been doped with a dopant which changes the work function of graphene. In an embodiment, the dopant is not chemically bonded to graphene. The dopant must nevertheless be close enough to the graphene to transfer charge to it. The use of differentially modified (e.g. differentially doped) graphene for the electrodes and/or the use of a gate electrode provide the asymmetry (i.e. potential difference) necessary for current to flow once the electron-hole pair is generated in the photoactive layer. Many prior art cells use additional layers to generate this asymmetry, using, for instance, both p- and n-doped materials between the two electrodes. Some even use a p-doped layer, an n-doped layer and an intrinsic layer between the two electrodes.

Thus, in an embodiment, the only active layers the cell contains are the first and second electrode layers and the layer comprising the transition metal dichalcogenide. What is meant by this is that no other layers are actively involved in the conversion of light to electric current (i.e. there are no other layers which are photoactive, conductive, p-doped or n-doped). In this embodiment, one or more intra-cell spacer layers (as described below in paragraphs [0055] to [0057]) may still be present. If so, the or each spacer layer takes no active part in the conversion of light to electric current.

In an embodiment, the photovoltaic cell further comprises a gate electrode. The gate electrode can be used to induce a potential difference between the first and the second electrode layer. In this embodiment, it may be that the first and second electrode layers are formed from the same material. Thus, it may be that both the first and second electrode layers comprise graphene.

Thus, it may be that both the first and second electrode layers is formed from one or more two-dimensional crystals of graphene.

In an embodiment, the first electrode layer comprises graphene or modified graphene with metal nanostructures on the surface of the graphene.

In an embodiment, the second electrode layer comprises graphene or modified graphene with metal nanostructures on the surface of the graphene.

The size, shape and distance between the nanostructures may be chosen according to the use to which the photovoltaic cell is being put. A series of disks 150 nm in diameter, the centres of which are 350 nm apart provide a resonance wavelength in the red region of the electromagnetic spectrum.

The metal nanostructures may be in any shape: squares, triangles, circles, rectangles, ovals etc. The nanostructures may be in the form of disks (or in other words, dots). Alternatively the nanostructures may be irregular in shape.

The nanostructures may have a largest dimension (measured in the plane of the graphene or modified graphene) of from about 10 nanometres to about 1000 nanometres. The nanostructures may have a largest dimension of from about 50 nm to about 500 nm. The nanostructures may have a largest dimension of from about 100 nm to about 200 nm. The nanostructures may have a largest dimension of about 150 nm. If the nanostructures are disks, the largest dimension will be the diameter of the disks.

The nanostructures may be separated by a distance, from centre of one nanostructure to the centre of the neighbouring nanostructure, of from about 100 nm to about 1000 nm. The nanostructures may be separated by a distance of from about 200 nm to about 500 nm. The nanostructures may be separated by a distance of from about 300 nm to about 400 nm. The nanostructures may be separated by a distance of about 350 nm.

In an embodiment, the nanostructures comprise one or more metals selected from: Au, Ag and Cu. In a particular embodiment, the nanostructures comprise Au. Thus, the nanostructures may substantially comprise Au. In a further embodiment, the nanostructures also comprise Cr. In an embodiment, the Cr is present in an amount lower than 20% by weight.

If present, nanostructures can increase the signal strength of the cell (i.e. the photocurrent generated by the cell). Without wishing to be bound by theory, the increased signal strength arises due to two effects, firstly they act as a dopant for the graphene layer upon which they are placed, secondly they have a plasmonic effect. The dopant effect works largely as described above. A plasmonic effect is where the incident light interacts with the electrons in the metal nanostructure generating a dramatic enhancement in the local electric field. The effect is very localised. In systems in which the layers are not so thin as those of the present invention, the effect would be too weak at the distance of the p-n junction for a plasmonic increase in the signal strength to be observed.

In an embodiment, the photovoltaic cell does not contain any rare earth metals. In a further embodiment, the first electrode layer does not contain any rare earth metals. Rare earth metals are commonly used in the transparent electrodes known in the art. Such metals are scarce and expensive. The use of graphene removes the need for these metals and reduces the cost and increases availability of the devices of the invention compared to those of the prior art.

The or each transition metal dichalcogenide (TMDC) layer is the photoactive layer. TMDCs are themselves structured such that each layer of the material consists of a three atomic planes: a layer of transition metal atoms (for example Mo, Ta, W . . . ) sandwiched between two layers of chalcogen atoms (for example S, Se or Te). Thus in one embodiment, the TMDC is a compound of one or more of Mo, Ta and W with one or more of S, Se and Te. There is strong covalent bonding between the atoms within each layer of the transition metal chalcogenide and predominantly weak Van der Waals bonding between adjacent layers. It is not necessarily the sole component which the photosensitive layer of the photovoltaic cell contains. Also, in some embodiments, there may be more than one photosensitive layer containing a TMDC layer and the different layers may be the same or different. In an alternative embodiment, there may be a single TMDC layer. In an embodiment, the or each TMDC layer is formed from a two-dimensional crystal of the TMDC.

The photovoltaic devices of the invention show good quantum efficiencies at low incident light levels. In addition, the devices are responsive to a wide range of visible light wavelengths.

In an embodiment, the TMDC is WS₂ or MoS₂. Both MoS₂ and WS₂ have potential for use in solar cells. Their potential for generating photocurrent peaks in the visible part of the spectrum and is roughly constant over 450-650 nm. In a further embodiment, the TMDC is WS₂ Bulk WS₂ has potential for use in solar cells, due in part to the size of its band gap (1.9/1.3 eV direct/indirect gap) and its large optical absorption which is greater than 107×10⁷ m⁻¹ across the visible range, meaning 95% of the light can be absorbed by a 300 nm film. A 2-D crystal of WS₂ is flexible. A further advantage of WS₂ is its chemical stability; meaning it does not undergo photocorrosion as silicon does. This stability, and the longevity which arises as a result, is inherent in WS₂. Existing materials for photovoltaic devices require additional processing steps to increase their longevity. The authors have surprisingly found that 2-D crystals of WS₂ are as effective at absorbing light as the bulk material. This is surprising because often the properties of two-dimensional crystals differ from the bulk properties of the same material due to the removal of the influence of the surrounding layers. Without wishing to be bound by theory, it appears that the electronic properties of WS₂ which give it its ability to absorb light are due to in-plane bonding, i.e. are not in any way due to the interactions between the layers.

In an embodiment, the layer of TMDC (e.g. the layer of WS₂) is from 2 to 100 nm thick. In another embodiment, the layer of TMDC (e.g. the layer of WS₂) is from 5 to 50 nm thick. In another embodiment, the layer of TMDC (e.g. the layer of WS₂) is from 10 to 30 nm thick. In another embodiment, the layer of TMDC (e.g. the layer of WS₂) is about 20 nm thick.

In an embodiment, the photovoltaic cell may further comprise one or more spacer layers. An intra-cell spacer layer may be situated on top of the first electrode layer (i.e. on the opposite side of the first electrode layer to the TMDC layer). An intra-cell spacer layer may be situated under the second electrode layer (i.e. on the opposite side of the second electrode layer to the TMDC layer). In an embodiment, the photovoltaic cell may further comprise two spacer layers, with a first spacer layer situated on top of the first electrode layer and a second spacer layer situated under the second electrode layer. In an embodiment, the or each spacer layer is transparent.

The or each spacer layer may comprise a dielectric material. The or each spacer layer may comprise an insulator. In an embodiment, the or each spacer layer comprises BN. Thus, the or each spacer layer may be formed from a two-dimensional crystal of BN. BN is a substantially transparent insulator. One purpose of the spacer layer(s) is to encapsulate one or both of the electrode layers. This may be of particular use in cases in which the electrode layer in question comprises a graphene or doped graphene. The spacer layer (and this is particularly true in cases where the or each intra-cell spacer layer is BN) increases the homogeneity of the graphene, increasing the efficiency of the cell. If the graphene is doped, the spacer layer (and this is particularly true in cases where the or each intra-cell spacer layer is BN) increases the homogeneity of the doping.

Thus, in a specific embodiment the photovoltaic cell comprises at least the following layers:
a first spacer layer;
a first electrode layer which comprises graphene or modified graphene (e.g. doped graphene);
a layer comprising a transition metal dichalcogenide;
a second electrode layer which comprises graphene or modified graphene (e.g. doped graphene); and
a second spacer layer;
wherein the layers are stacked sequentially in the order described to form a laminate structure.

The photovoltaic cell may be flexible. Flexible means that shaping the cell (e.g. by bending, rolling or moulding it) does not damage the cell or significantly impede the working of the cell. Many existing photovoltaic technologies are rigid and fragile. This limits the applications for many existing technologies to those in which the cell is fixed in a plane.

In an embodiment, the only active layers the cell contains are the first and second electrode layers and the layer comprising the TMDC. What is meant by this is that no other layers are actively involved in the conversion of light to electric current (i.e. there are no other layers which are photoactive, conductive, p-doped or n-doped). In this embodiment, one or more intra-cell spacer layers (as described above in paragraphs [0055] to [0057]) may still be present. If so, the or each spacer layer takes no active part in the conversion of light to electric current.

In an embodiment is provided a light harvesting device comprising one or more photovoltaic cells according to the third aspect of the invention. In an embodiment, the light harvesting device comprises a plurality of photovoltaic cells according to the third aspect of the invention.

In an embodiment, the photovoltaic cells are stacked vertically. This does not exclude the possibility that the photovoltaic cells are also adjacent to each other as well as being stacked vertically, in which case the device comprises a plurality of stacks of photovoltaic cells. In this embodiment, the second electrode should be substantially transparent. Thus, in a specific embodiment, the second electrode comprises graphene or modified graphene.

It is preferable that the cells comprise spacer layers. In this embodiment, the spacer layers provide a separation between the photovoltaic cells. The inter-cell spacer spacer layers should be substantially transparent.

In a fourth aspect of the invention is provided a heterostructure comprising:
a first layer which comprises graphene or modified graphene (e.g. doped graphene);
one or more layers comprising WS₂;
a second layer which comprises graphene or modified graphene (e.g. doped graphene);
   wherein the layers are stacked sequentially to form a laminate structure and the or each layer of WS₂ is situated between the first and the second graphene layer.

The heterostructure may be a two-dimensional heterostructure.

In a specific embodiment the heterostructure comprises at least the following layers:
a first spacer layer;
a first layer which comprises graphene or modified graphene (e.g. doped graphene);
a layer comprising WS₂;
a second electrode layer which comprises graphene or modified graphene; and
a second spacer layer;
wherein the layers are stacked sequentially in the order described to form a laminate structure.

The heterostructure is preferably a two-dimensional heterostructure. Where appropriate, the embodiments described above for the photovoltaic cells of the third aspect of the invention may apply equally to the heterostructures of the fourth aspect of the invention. Thus, where appropriate the features of the first and second electrode layers of the third aspect described in paragraphs [0029] to [0049] above may equally apply to the first and second layer of graphene or modified graphene of the fourth aspect. The features of the transition metal chalcogenide of the third aspect described in paragraphs [0053] and [54] above may apply to the WS₂ layer of the fourth aspect. The heterostructures of the fourth aspect may comprise a spacer layer as described in relation to the third aspect in paragraphs [0055] to [0057] above.

The use of WS₂ is particularly advantageous in a heterostructure because flexible structures can easily be made. Photovoltaic cells made from such a heterostructure can therefore be used in a variety of applications and environments which are not currently accessible to known photovoltaic cells.

The heterostructures of the fourth aspect may be for use in the manufacture and/or repair of photovoltaic cells, including those of the first and third aspects.

Where the heterostructures of the fourth aspect are two-dimensional heterostructures, they may be the two dimensional heterostructures of the first and second aspects of the invention.

In a fifth aspect of the invention is provided a method of making a heterostructure according to the fourth aspect, the method comprising:
suspending a transition metal dichalcogenide (e.g. WS₂) in a liquid; and
depositing the transition metal dichalcogenide onto a surface to form a thin film.

The surface is an electrode layer or a spacer layer of the laminate that is ultimately formed. The heterostructure is preferably a two-dimensional heterostructure.

In an embodiment, the method further comprises:
subjecting the suspension of the transition metal dichalcogenide in the liquid to ultrasound.

In an embodiment, the suspension is in a sealed flask. In a further embodiment, the suspension is subjected to ultrasound for from 12 to 24 hours. The ultrasound breaks up the transition metal dichalcogenide into particles which comprise a few molecular layers (e.g. from 1-10 molecular layers). This improves the distribution of the transition metal dichalcogenide on the surface.

In an embodiment, the method further comprises:
using a centrifuge on the suspension to remove any aggregated transition metal dichalcogenide.

The deposition step can be achieved by drop casting. Alternative methods of deposition are spin-coating and the Langmuir-Blodgett technique.

In an embodiment, the liquid is a polar protic solvent, e.g. water or a C₁-C₄ alcohol (such as ethanol).

In an embodiment, the surface is the first electrode layer of the first aspect or the first graphene layer of the second aspect. In an alternative embodiment, the surface is the second electrode layer of the first aspect or the second graphene layer of the second aspect. The surface may be a layer of graphene or modified graphene (e.g. doped graphene). Alternatively, the surface may be a spacer layer (e.g. one comprising BN) as described above.

The method may further comprise:
depositing a layer of graphene on the thin film of transition metal dichalcogenide.

The graphene deposition can be achieved using a method similar to that described for the transition metal dichalcogenide above (i.e. suspending graphite in a liquid, subjecting the suspension to ultrasound, removing aggregates using a centrifuge and deposition) or it can be achieved using chemical vapour deposition.

In an embodiment, the method of making a heterostructure is a method of making a photovoltaic cell. The method of making a photovoltaic cell may be a method of making a photovoltaic cell according to the third aspect.

Where the heterostructures made according to the fifth aspect are two-dimensional heterostructures, they may be the two dimensional heterostructures of the first and second aspects of the invention.

This method of making a thin film of a transition metal dichalcogenides is known as chemical exfoliation. It is a cheap and easy method for manufacturing thin films of materials in large quantities. A further benefit of using transition metal dichalcogenides (and particularly WS₂) in the photovoltaic cells of the invention is that this method of manufacture can be used and the cost of the photovoltaic cells made by this invention can be expected to be considerably lower than the photovoltaic cells currently available (or at least those with energy conversion efficiencies which are comparable to the cells of the present invention) as a result.

### BRIEF DESCRIPTION OF THE DRAWINGS

Embodiments of the invention are further described hereinafter with reference to the accompanying drawings.

FIG. 1 shows the dimensions of an exemplary polymer stack onto which flakes are exfoliated for transfer.

FIG. 2 shows the dimensions of an exemplary device.

FIG. 3 shows the dimensions of the plasmonic nanostructures of an exemplary device.

FIG. 4 shows a representative optical image of one of a device according to the invention (left hand top panel); a schematic diagram of the device (right hand top panel); and photocurrent maps taken before (above) and after (below) the device was stored in a humid atmosphere (bottom panel).

FIG. 5 shows IV curves taken at gate voltage values from −20 to +20 V in 10 V steps.

FIG. 6 shows the IV characteristics of the device shown under laser illumination of varying intensity.

FIG. 7 shows the extrinsic quantum efficiency of the devices. The inset shows the photocurrent for a device on Si/SiO₂ (open squares) and for a flexible device on PET (crossed squares).

FIG. 8 shows a comparison of photocurrent signal as a function of gate voltage; before and after thermal evaporation of a 1 nm thick gold film. Taken at zero bias.

FIG. 9 shows a photocurrent map of the nanostructured device B.

### DETAILED DESCRIPTION

The term ‘two-dimensional heterostructure’ refers to a plurality of two-dimensional crystals arranged in a stack. A heterostructure comprises at least two different materials. The two-dimensional crystals are arranged such that the heterostructures are substantially parallel, being arranged face-to-face, forming a laminate. Such heterostructures may also be called vertical heterostructures. Various structures may be intercalated between the crystals e.g. nanoparticles, nanotubes, quantum dots and wires. It may be, however, that the heterostructure is formed entirely of two-dimensional crystals. This does not preclude the heterostructure from being mounted on a substrate and/or have a protective coating. Nor does it preclude the possibility that nanostructures are present but are not intercalated between the layers. A two-dimensional heterostructure is so-called because it is comprised of two-dimensional crystals. It will itself, of course, be a three dimensional structure.

Examples of two-dimensional crystals which may be included in the heterostructures of the invention include graphene, modified graphene (e.g. graphene, fluorographene, chlorinated graphene), BN, MoS₂, NbSe₂, Bi₂Te₃, MgB₂, WS₂, MoSe₂, TaSe₂, NiTe₂.

Heterostructures may be formed by placing two-dimensional crystals upon one another mechanically, epitaxially, from solution and/or using any other means which would be apparent to the person skilled in the art.

A graphene heterostructure comprises at least one two-dimensional crystal of graphene or modified graphene.

The term ‘two dimensional crystal’ means a crystal which is so thin that it exhibits different properties than the same material when in bulk. Not all of the properties of the material will differ between a two-dimensional crystal and a bulk material but one or more properties are likely to be different. A more convenient definition would be that the term ‘two-dimensional crystal’ refers to a crystal that is 10 or fewer molecular layers thick, e.g. one molecular layer thick, but this depends on the material. Crystals of graphene which have more than 10 molecular layers (i.e. 10 atomic layers; 3.5 nm) generally exhibit properties more similar to graphite than to graphene. A molecular layer is the minimum thickness chemically possible for that material. In the case of graphene one molecular layer is a single atom thick. The same is true of boron-nitride. In the case of the transition metal dichalcogenides (e.g. MoS₂ and WS₂), a molecular layer is three atoms thick (one transition metal atom and two chalcogen atoms). Thus, two-dimensional crystals are generally less than 50 nm thick, depending on the material and are preferably less than 20 nm thick. Graphene two-dimensional crystals are generally less than 3.5 nm thick and may be less than 2 nm thick.

The term ‘two dimensional crystal’ includes crystals which are doped, as described below.

The term ‘modified graphene’ refers to a graphene-like structure that has been modified in some way. Thus, the modified graphene may be graphene which has been doped. This may have the purpose of modifying the work function of graphene without significantly reducing its conductivity. Examples of compounds which can be used to dope graphene are: NO₂, H₂O and I₂, which act as acceptors to provide a p-doped graphene; or NH₃, CO and C₁-C₃ alcohols (e.g. ethanol), which act as donors to provide an n-doped graphene. Small amounts of doping can increase the transparency of the doped graphene relative to graphene but the dopant itself may absorb or reflect light. Conventional methods of doping the graphene can be used to improve the functionality of the graphene, including its transparency to actinic radiation. These methods of doping are described in the literature and are not therefore reproduced here. An alternative approach to doping is to place metal (e.g. gold) nanostructures on the surface of the graphene. This will both dope the graphene and increase the local electric field. A preferred dopant is one which is not chemically bonded to graphene but which is able to transfer charge to graphene, effectively altering the graphene's work function.

When graphene is placed in contact with a transition metal dichalcogenide layer, there is a dopant effect, i.e. the graphene's work function is changed. Thus, for the absence of doubt, throughout this specification, whenever graphene is referred to as being doped, this means that it is doped by something in addition to the TMDC.

An electrode layer is a layer of a material which is an electrical conductor.

A heterostructure is a structure comprising two or more different materials. The materials may be arranged in any way in relation to each other.

As use in this specification, a ‘layer’ of a material refers to a plane of that material. Each ‘layer’ may comprise any number of molecular layers of the same chemical composition. Thus a layer of graphene does not necessarily mean a graphene monolayer, although it might. Likewise, a layer of WS₂ does not necessarily refer to a WS₂ monolayer, although it might. In many embodiments of this invention, a ‘layer’ of any material means a two dimensional crystal of that material.

### Preparation of Two-Dimensional Crystals and Two-Dimensional Heterostructures

### Large Scale Production of Graphene

There are many ways of producing graphene. These include CVD, liquid exfoliation, mechanical cleavage and all of these methods are suitable for the production of photovoltaic cells and devices according to this invention (see examples). The following is a continuous method by which large sheets of monolayer graphene can be produced.

The fact that this ‘roll-to-roll’ method is a continuous process allows the industrial production of graphene on a scale suitable for the production of the photovoltaic devices and cells described in this application. There are three essential steps in this roll-to-roll process.
1. Adhesion of an adhesive scaffold to graphene after growth on copper.
2. Removal of copper (leaving graphene attached to the tape above).
3. Transfer of graphene to another substrate (usually a transparent polymer film such as PET to form a conductive coating) and removal of the carrying tape layer.

The growth process is as follows:
1. A quartz tube is used as a reactor furnace for the growth. A 30 inch long copper film can be inserted into the furnace.
2. The copper is annealed in H₂ gas flow at 1000° C. to increase copper grain size.
3. Growth of monolayer graphene then occurs at a temperature of 1000° C. when a mixture of H₂ and CH₄ (methane) is allowed into the chamber followed by rapid cooling under H₂ flow.
4. Thermal release tape is then applied to the surface of the graphene by passing the tape/graphene/copper film between two rollers.
5. This combined system is then passed through a bath of copper etchant and rinsed to remove the copper film.

Finally, the graphene/tape film is passed—along with the target substrate—through another set of rollers while being exposed to a temperature of around 100° C. to cause the tape to be released from the graphene surface, leaving the final product.

It is possible to dope graphene in the same process.

### Preparation of Other Two-Dimensional Crystals

Two-dimensional materials can be made in bulk using the following technique for the exfoliation of a large number of layered crystals. The crystals come in commercially available powder form with flakes 1-10 microns in size. The crystals are placed in one of various solvents in a phial and placed in an ultrasonic bath. The 20 best solvents for WS₂, MoS₂ and BN are listed in Table 1 below. The ultrasound passing through the water breaks up the crystals so the layers separate and become dispersed in the solvent. Their lateral size in also reduced as it is quite aggressive procedure. The resultant flakes have a flake size of between 10 nm and 1 micron depending on the material. This mixture can then be subjected to centrifugation.

TABLE 1
(Taken from: J. Coleman, Two-dimensional Nanosheets Produced by Liquid Exfoliation
of Layered materials” Science, vol 331, no 6017, pp 568-571, 2011)

| | BN | | MoS₂ | | WS₂ | |
|---|---|---|---|---|---|---|
| | | A/1 (AU) | | A/1 (AU) | | A/1 (AU) |
| | Solvent | 300 nm | Solvent | 670 nm | Solvent | 630 nm |
| 1 | Cyclohexyl- | 100 | NVP | 100 | DMSO | 100 |
| | pyrrolidinone | | | | | |
| | (CHP) | | | | | |
| 2 | N-dodecyl- | 61 | N8P | 98 | NVP | 92 |
| | pyrrolidone (N12P) | | | | | |
| 3 | Benzyl Benzoate | 44 | N12P | 97 | NMF | 90 |
| 4 | Isopropanol | 44 | CHP | 88 | N12P | 84 |
| 5 | N-Octyl- | 44 | NMP | 80 | DMEU | 75 |
| | pyyrolidone (N8P) | | | | | |
| 6 | N-vinyl- | 41 | DMEU | 73 | DMF | 73 |
| | Pyrrolidinone | | | | | |
| | (NVP) | | | | | |
| 7 | Benzyl Ether | 40 | DMSO | 61 | Benzyl | 71 |
| | | | | | benzoate | |
| 8 | Dimethyl- | 36 | DMF | 54 | CHP | 69 |
| | imidazolidinone | | | | | |
| | (DMEU) | | | | | |
| 9 | Cyclohexanone | 29 | DMA | 54 | Cyclohexanone | 63 |
| 10 | Chlorobenzene | 28 | Benzaldehyde | 51 | Benzonitrile | 59 |
| 11 | Dimethylsulphoxide | 27 | Benzonitrile | 47 | N8P | 59 |
| | (DMSO) | | | | | |
| 12 | Benzonitrile | 26 | Benzyl | 46 | Isopropanol | 59 |
| | | | benzoate | | | |
| 13 | Chlorobenzene | 25 | NMF | 41 | DMA | 57 |
| 14 | Chloroform | 23 | Cyclohexanone | 38 | Benzylether | 55 |
| 15 | Bromobenzene | 23 | Isopropanol | 32 | Chlorobenzene | 45 |
| 16 | N-methyl- | 23 | Quinoline | 26 | Methanol | 45 |
| | pyrrolidinone | | | | | |
| | (NMP) | | | | | |
| 17 | N-Methyl | 21 | Acetone | 24 | Formamide | 40 |
| | Formamide (NMF) | | | | | |
| 18 | Dimethylformamide | 18 | Benzylether | 23 | Bromobenzene | 29 |
| | (DMF) | | | | | |
| 19 | Dimethylacetamide | 16 | Cyclohexane | 22 | Quinoline | 26 |
| | (DMA) | | | | | |
| 20 | Formamide | 9 | Methanol | 21 | Acetone | 17 |

The centrifugation process involves spinning a phial of the dispersion at a high rpm in order to separate the large flakes from the smaller ones. The result is a dispersion with a gradient in the concentration with the thick large heavy flakes at the bottom. The low concentration dispersion with the small flakes can be removed from the top using a pipette or other method.

If a paper is wanted, this solution can be filtered to remove a laminate of the flakes assembled in a roughly planar structure.

An alternative intercalation process can be used for the preparation of TaS₂ two-dimensional crystals. The crystals are grown by vapour transport. This process involves placing tantalum and sulphur in a quartz tube with a transport gas such as iodine which carries the constituents down a temperature gradient and allows deposition of the resultant crystal. This is usually done at temperatures of around 800-1000° C.

The crystals are removed from the growth chamber and exposed to n-butyl lithium in a water free environment. The n-butyl lithium penetrates between the layers and subsequent exposure to water leads to a reaction between Li and water. This reaction releases hydrogen gas that pushes the layers apart. A suspension of thin flakes is left in the water which can then be drop cast onto a desired substrate.

### Preparation of Two-Dimensional Heterostructures

A clean and precise technique for the manual transfer of thin crystal flakes to the surfaces of one another is as follows. This method can be used in the preparation of complex stacks of multiple layers and also in the preparation of complex devices. The technique is generally applicable but is described below in connection to hBN/graphene heterostructures.

The technique involves various steps as follows:
1. Single crystal hBN flakes were deposited on an oxidised silicon wafer using the ‘scotch tape’ technique, i.e. bulk crystals are peeled many times with adhesive tape and pressed onto the oxidised silicon substrate. Some proportion of the resultant debris will be single crystal hBN flakes with a thickness on the order of 30-50 nm, a suitable thickness substrate to eliminate roughness from SiO₂.
2. Separately, a bilayer polymer stack is spin coated onto another substrate. A graphene flake is deposited—by the same method as described above—onto this polymer stack. The two different polymers are not soluble in the same solvent. This way the bottom one can be selectively dissolved (by water in this case) without affecting the top layer which is carrying the graphene. The top layer—now floating on top of the solvent—can be picked up on a glass slide, inverted and positioned about the hBN flake under an optical microscope. The two are carefully brought into contact. The sacrificial top polymer layer is then dissolved in another solvent to leave the hBN/graphene stack.

The stack is made of a water soluble polymer layer and PMMA which can be dissolved in acetone.

### Further Discussion of the Invention

This invention generally relates to new applications of graphene. Specifically, the invention relates to new graphene heterostructures, applications of graphene heterostructures and methods of making graphene heterostructures.

It is an aim of the invention to provide methods of making graphene heterocycles which are more energy efficient than existing methods. The methods may be quicker than existing methods. They may generate less waste than existing methods.

It is an aim of this invention to provide methods which allow access to graphene heterostructures which it is not possible to make using existing methods.

It is an aim of this invention to provide methods which allow the efficient production of graphene heterostructures on a larger scale than existing methods.

A further aim of the invention is the provision of new graphene heterostructures. These heterostructures may have similar properties to existing graphene heterostructures but be easier to produce. The new graphene heterostructures may have improved properties compared to known graphene heterostructures, or they may have improved properties compared to known non-graphene based materials. The graphene heterostructures may have new properties not previously observed in graphene heterostructures. In particular, the new heterostructures may have new combinations of properties not previously observed in a single material, whether that material is graphene based or not graphene based.

Another aim of the invention is to provide heterostructures for use in new photonics devices, such as LEDs and photovoltaic devices. The heterostructures may be for use in new electronic devices, such as transistors.

Further aims of the invention will be made clear in the following sections:

### Introduction to the Further Discussion of the Invention

Technological progress is determined, to a great extent, by developments in material science. The most surprising breakthroughs are attained when a new type of material, or new combinations of known materials, with different dimensionality and functionality, are created. Well-known examples are the transition from three-dimensional (3D) semiconducting structures based on Ge and Si to 2D semiconducting heterostructures, nowadays the leading platform for microelectronics. Other examples are quantum wells formed at GaAs/AlGaAs semiconductor interfaces for high electron mobility transistors, magnetic multilayers for hard discs, and solar cells based on 2D organic LEDs. Ultimately, the limits and boundaries of certain applications are given by the very properties of the materials naturally available to us. Thus, the band-gap of Si dictates the voltages used in computers, and the Young's modulus of steel determines the size of the construction beams.

Here we describe a new paradigm in material science, physics, engineering and nanotechnology: heterostructures based on 2-dimensional crystals that will decouple the performance of particular devices from the properties of naturally available materials. The ultimate goal is to develop a new paradigm of “materials on demand” with properties precisely tailored for novel complex architectures and structures.

Our general approach is based on our combined know-how and unique expertise in the new class of 2D atomic crystals, such as graphene, graphane, fluorographene, monolayers of BN and MoS₂, etc. Individual 2D crystals can be arranged into heterostructures, thus creating stacks with novel properties, very different from those of individual components. It is also possible to intercalate metal nanoparticles, nanotubes, semiconductor quantum dots (QD) and wires, to create novel 1D-2D compounds.

Heterostructures have already played a crucial role in technology, giving us semiconductor lasers and high-mobility field effect transistors (FET). However, thus far the choice of materials has been limited to those which can be grown (typically by molecular beam epitaxy) one on top of another, thus limiting the types of structures which can be prepared. Instead, 2D crystals of very different nature can be combined in one stack with atomic precision, offering unprecedented control on the properties and functionalities of the resulting 2D-based heterostructures. One can create such layered heterostructures by placing individual 2D crystals mechanically, epitaxially, from solutions. 2D materials with very different properties can be combined in one 3D structure, producing novel, multi-functional materials. An alternative class of nanostructures will also be investigated by combining metal or semiconductor nanoparticles (eg gold, Nanodiamond, CdSe, PbSe, PbS, etc) with the 2D superstructures. Solution processing, self-assembly, intercalation and lithography will allow an entire new class of hybrid structures.

Most importantly, the functionality of such heterostructures is not simply given by the combined properties of the individual layers. Interactions and transport between the layers allow one to go beyond simple incremental improvements in performance and create a truly “quantum leap” in functionality.

These 2D heterostructures can change the whole paradigm of material science. By combining materials with very different properties, we are no longer limited by a single set of parameters. The resulting 3D structures will combine conductivity of one 2D crystal, strength of another, chemical reactivity of the third and the optical properties will be determined by the whole heterostructure. By carefully choosing and arranging the individual components one can tune the parameters, creating materials with tailored properties, or “materials on demand”. Following this novel approach, part of the functionality is brought to the level of the design of the material itself (usually it is done only when creating a structure from a given material).

### Background to the Further Discussion of the Invention

The class of 2D atomic crystals started with graphene—a monolayer of carbon atoms arranged into a hexagonal lattice. It is a remarkable material with myriads of unique properties, from electronic to chemical and from optical to mechanical. It has also opened a floodgate for many other 2D crystals to be discovered and studied. Such crystals are stable, mechanically strong and carry many properties which cannot be found in their 3D counterparts. Our research has also shown that such two-dimensional crystals have an unexpectedly high electronic quality. This has generated a flood of further experimental discoveries. The research subject remains one of the most active within the whole areas of physics, materials science and nanotechnology. Among nearly a dozen of atomically thin materials that were demonstrated so far, graphene stands out due to its unique electronic spectrum and ballistic transport on a micron scale under ambient conditions. It is the strongest material available to us, its conductivity is millions higher than copper, it has very high thermal conductivity, etc. The linear dispersion of the Dirac electrons combined with the strong and peculiar interaction with light, makes graphene ideal for photonics and optoelectronics. The fact that graphene is an ultra-thin material plays an important role allowing the ambipolar electric field effect, and unrivalled electrostatics for scaling of electronic devices to nm sizes.

Applications are no longer wishful thinking, and graphene can now be produced in industrial quantities. Within the short 7 years period, this research has moved from academic to industrial labs, which will continue to support strong interest in graphene for years to come. The other 2D crystals carry a range of interesting complementary properties. BN is an insulator with a large band gap (˜6 eV) and even a single layer creates a tunnelling barrier with resistance of about lkΩ-μm². It is sometimes called “insulating graphite” and it might be used in instances where graphene's high conductivity is a disadvantage (ultra-thin, high quality, insulating layers for nano-electronics, non-conductive, ultra-strong, composite materials). MoS₂ is a semi-conductor and provides a smaller tunnelling barrier, its band-gap is ideal for optoelectronics. NbSe₂ is a superconductor, Bi₂Te₃—topolical insulator, etc.

### Mechanical Exfoliation of Layered 3D Crystals

This is the most “quick & easy”, as well as efficient method for 2D crystals production. Several materials (graphene, monolayers of BN, MoS₂) have already been created by this method, and those usually demonstrate very high electronic and crystallographic quality. The properties of the 2D crystals are typically very different from those of their 3D precursors; graphite is semimetal, while the overlapping between the valence and the conduction bands in mono- and bi-layer graphene is exactly zero. Bulk MoS₂ is an indirect-gap semiconductor, while its monolayer has a direct band gap. However, there is still a large number of other layered materials which potentially can be cleaved and prepared as monolayers. Most interesting are Bi₂Te₃ as topological insulator, NbSe₂ and MgB₂ as superconductor and many others. Furthermore, often several layers of such materials would possess properties which are intermediate (or even completely different) between monolayer and bulk. A broad range of techniques (transport, TEM, AFM, Raman, optic) can be used for characterisation of the new 2D crystals.

### Liquid Phase Exfoliation (LPE)

A mass-scalable approach to 2D crystals is to exfoliate their bulk counterparts via chemical wet dispersion followed by ultrasonication, both in aqueous and non-aqueous solvents. This technique offers many advantages for cost reduction and scalability. The lateral size of the layers can be controlled from few nanometers to microns. The number of layers can also be controlled via separation in centrifugal fields or by combination with density gradient ultracentrifugation (DGU). The availability of solutions and dispersions opens up a range of applications in composites, thin films and inks. Inks can be printed in a variety of ways, and mixed to create hybrids. Many applications in photonics and optoelectronics, such as transparent conductors, third generation solar cell electrodes, and optical-grade polymer composites will benefit from LPE produced and assembled materials. LPE can also produce ribbons with widths <10 nm, allowing a further in-plane confinement of the 2D materials, thus an extra handle to tailor their properties. LPE does not require transfer techniques and the resulting material can be deposited on different substrates (rigid and flexible) following different strategies such as dip and drop casting, spin, spray and rod coating, ink-jet printing, etc. Several layered materials (including MoS₂, WS₂, MoSe₂, MoTe₂ TaSe₂, NbSe₂, NiTe₂, BN, and Bi₂Te₃) have been successfully exfoliated using this simple, yet efficient method. This approach may also influence the chemical stability, as the layer of liquid might protect those crystallites from oxidation. Such suspensions allow easy assembling of the materials into superstructures.

### Chemical Modification of Existing 2D Crystals

This is a powerful method for the synthesis of 2-D crystals. As an example graphene can be considered as a giant molecule, which can be modified through chemical reactions. Several stable graphene derivatives have been already produced including graphane, fluorinated and chlorinated graphene. Clearly it is only the beginning and many other materials with very different properties are possible. It is expected that other 2D materials are similarly versatile and allow as many chemical modifications as graphene does. Separate chemical modification of the two sides of a 2D crystal allows an electric moment can be created across the crystal and lead to new, unexpected properties. Also, chemical modifications can be used as a tool to provide a fine control over the distance between neighbouring planes in the 2D heterostructures. This will also be done by intercalation or by placing other metallic and semiconducting nanostructures between the planes.

### Mechanical Transfer

Transfer of individual 2D crystals into heterostructures has been developed and has already led to the observation of several interesting effects, including fractional quantum Hall effect, ballistic transport and metal-insulator transition in graphene. An additional advantage is the possibility to control/modify each individual layer as it is being deposited. Such chemical modification is possible at any stage of the transfer procedure. Also, any atomic layer in the stack can be individually contacted, offering unprecedented control on the properties of the stack (effectively we have a material with contacts to every individual atomic plane). It has been demonstrated that local strain can significantly modify the band structure of graphene and other 2D crystals. Thus, it is possible to apply strain, locally produced by AFM tip, for additional control on the electronic and optical properties of the stacks. Also important is the control of the relative orientation of the layers. Realistic control of 0.2° rotation between them would allow fine control over the electronic properties of the stack.

Heterostructures Deposited from Suspensions

Large scale placement of LPE samples can be achieved by spin coating and Langmuir-Blogdett. Surface modifications by self-assembled monolayers enable targeted large-scale deposition. High uniformity and well defined structures on flexible substrates can also be obtained. Di-electrophoresis can also be used to control the placement of individual crystals between pre-patterned electrodes. Inkjet printing allows to mix and print layers of different materials and is a quick and effective way of mass-production of such systems. Although the quality of the resulting structures can be significantly lower than that obtained by mechanical or CVD methods, it is still be suitable for a number of photonics and optoelectronics applications, as well as for applications in thin film transistors, RF tags, solar cells, batteries and supercapacitors.

### CVD Growth

CVD is in principle the most powerful method for mass production of the heterostructures. Graphene and graphene layers can now be grown on various substrates (Ni, Cu, Ir, Ru, etc) when the latter are exposed to hydrocarbon gases, such as benzene, ethane, and methane, with a suitable reaction temperature. Reduction of growth temperature is desirable in order to cut production costs, and directly integrate with CMOS processing. Plasma-enhanced CVD can be used to lower growth temperature. Unsupported flakes can also be produced. A major factor impacting large-scale production of graphene-based nano-electronic devices is access to high-quality graphene layers on insulating substrates. There are several indications that the growth of other 2-D materials is indeed feasible. Hexagonal boron nitride (h-BN) has already been shown to be effective as a substrate for graphene CVD. In fact, CVD graphene on h-BN has shown remarkable mobilities, much higher than for graphene grown on metal substrates.

MBE is an Ultra-High-Vacuum-based growth technique for producing high quality epitaxial structures with monolayer control. Since its introduction in the 1970s as a tool for growing high-purity semiconductor films, MBE has evolved into one of the most widely used techniques for epitaxial layers of metals, insulators and superconductors, both at the research and the industrial level. MBE was demonstrated an effective tool to grow carbon films directly on Si(111) and is a promising approach to achieve high-purity graphene heterostructures on a variety of substrates such as SiC, Al₂O₃, Mica, SiO₂, Ni, etc. MBE is also quite promising for in situ growth of hetero- and hybrid structures, combining graphene and semiconductors.

### Electronic Transport in Lateral and Vertical Structures

Vertical and lateral transistors are the first and most natural application of atomically thin heterostructures and multilayer systems. Vertical heterostructures and tunnel devices have been used for many years, from the Esaki diode to cascade lasers. 2D-based heterostructures offer a unique prospect of extending the existing technologies to their ultimate limit of using monolayer-thick tunnel barriers and quantum wells. At the same time, since the doping-dependent screening properties of graphene can be controlled electrically, graphene sheets and thin ribbons in multilayer structures can be used as gates with widely variable properties—a functionality hardly offered by any other material. We believe that heterostructures, built by one of the methods listed above, offer unique opportunities to study transport properties of complex, interacting systems (for example, exciton condensation) and to use such structures for transistor with significantly improved transfer characteristics, sensors and other applications. Vertical devices can also be scaled to one nm laterally, as far as lithography techniques allow.

### Tunnelling Devices and Resonant Tunnelling

Tunnelling devices based on 2D heterostructures have been demonstrated, showing that BN can act as an excellent defect-free tunnel barrier. The BN monolayer separating two graphene electrodes provides a high-quality tunnel barrier and allows biases as large as 1V without electrical breakdown. The first experiments on exfoliated Gr/BN/Gr structures (“Gr” stands for “graphene”) demonstrate a complex non-linear tunnelling I-V.

There are various types of devices where quantum tunnelling us used (for example, tunnelling magnetoresistance devices or resonant tunnelling diodes). Automatically thin, smooth and continuous barriers offered by the use of 2D crystals can dramatically improve quality and characteristics of any existing or considered scheme involving quantum tunnelling.

### Photovoltaic Devices

We will create superstructures composed of two metallic plates separated by a barrier with modulated profile. Type-I quantum wells can be formed and injection of electrons and holes with subsequent recombination will lead to light emission. Using more complicated structures, both type-I and type-II quantum wells of various configurations can be created. As the band-structure of 2D materials depends on the number of layers, simply by changing the thickness of one of the components we could strongly tune the resulting optical properties.

Photovoltaic devices can be created by placing two metallic 2D crystals (for instance graphene) within tunnelling proximity of each other. An example would be two graphene layers, separated by several layers of BN, which serves as a tunnelling barrier. Electric field separates the electron hole pair which is created by an incoming photon, resulting in photocurrent. By applying a bias voltage (or by using proximity effect of other metallic 2D crystals) electric field will be created inside the barrier. Any e-h pair excited by light is separated and contribute to photocurrent. It is possible to create heterostructures with various band gaps, sensitive to photons of different energies.

### Active Plasmonic

Combinations of 2D heterostructures with plasmonics allows for the creation of active optical elements. 2D heterostructure are ideally suited to be used with plasmonic structures, as they can be positioned exactly at the maximum of electric field from plasmonic nanostructures. Such elements are of great importance in different areas of science and technology: from ubiquitous displays, to high tech frequency modulators. Despite great progress in optical disciplines, active optics still relies heavily on either liquid crystals, which guarantee deep modulation in inexpensive and small cells, but are quite slow, or non-linear optical crystals, which are fast, but bulky and expensive. Thus, the development of inexpensive, fast and small active optical elements would be of considerable interest.

Plasmonic metamaterials of various configurations can be sandwiched between Gr/BN heterostructures (e.g. golden dots can be placed between two graphene/BN sandwiches). The conductivity of graphene can be changed several orders of magnitude by electrostatic doping. Such change could modulate the optical properties of the underlying plasmonic structure. The combination of 2D heterostructures with plasmonics could result in fast, cheap and small active optical elements.

Throughout the description and claims of this specification, the words “comprise” and “contain” and variations of them mean “including but not limited to”, and they are not intended to (and do not) exclude other moieties, additives, components, integers or steps. Throughout the description and claims of this specification, the singular encompasses the plural unless the context otherwise requires. In particular, where the indefinite article is used, the specification is to be understood as contemplating plurality as well as singularity, unless the context requires otherwise.

Features, integers, characteristics, compounds, chemical moieties or groups described in conjunction with a particular aspect, embodiment or example of the invention are to be understood to be applicable to any other aspect, embodiment or example described herein unless incompatible therewith. All of the features disclosed in this specification (including any accompanying claims, abstract and drawings), and/or all of the steps of any method or process so disclosed, may be combined in any combination, except combinations where at least some of such features and/or steps are mutually exclusive. The invention is not restricted to the details of any foregoing embodiments. The invention extends to any novel one, or any novel combination, of the features disclosed in this specification (including any accompanying claims, abstract and drawings), or to any novel one, or any novel combination, of the steps of any method or process so disclosed.

The reader's attention is directed to all papers and documents which are filed concurrently with or previous to this specification in connection with this application and which are open to public inspection with this specification, and the contents of all such papers and documents are incorporated herein by reference.

### Example 1

### Preparation of and Photovoltaic Ability of a Graphene/WS₂/Graphene Device

The experiments described in the following sections demonstrate a beneficial combination of the properties of graphene and WS₂: WS₂ as a good photoactive material and graphene as a good transparent electrode. Using a graphene/WS₂/graphene stack with appropriately positioned Fermi levels and simply doping the two graphene layers differently (either by electrostatic gating or chemical methods), leads to large photocurrent. The layered nature of our structures means it is possible to fabricate large area light harvesting devices. Without illumination, such devices act as tunnelling transistors.

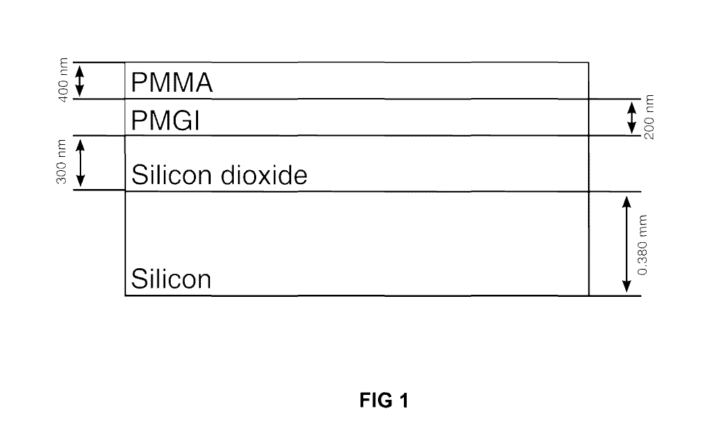

Devices comprising three principal layers, top and bottom graphene electrode layers (we tested both micromechanically cleaved and CVD-grown graphene) sandwiching a photoactive WS₂ layer, were prepared. The left hand panel in FIG. 1 shows an optical image of a device according to the invention. In the fabrication procedure, the flakes were transferred with the so called ‘dry transfer’ technique (in the case of micromechanically cleaved graphene) with thorough annealing (H₂/Ar (10:90) at 200° C. for 3 hrs) at each stage to ensure minimal contamination between the layers and low level doping of the graphene layers. Hexagonal boron nitride (hBN) was chosen as both a substrate and an encapsulating layer to achieve a higher doping homogeneity and spacer to a carefully define the contact region. Thus, the final structure of a typical device on top of the oxidised silicon wafer was graphene/hBN/WS₂/graphene/hBN. Here, the SiO₂/hBN could be used as the gate dielectric. A series of such structures was produced where the thickness of the WS₂ layer was varied from ˜5-50 nm. Devices with WS₂ thickness of ˜20 nm were chosen for the devices presented here because they were found to absorb a fair proportion of incident photons and still allowfull characterisation by tunnelling spectroscopy.

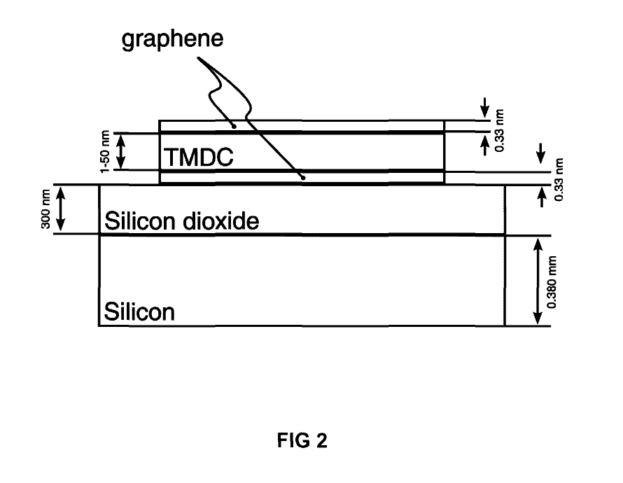

A stepwise summary of an exemplary process for preparing the heterostructures, cells and devices according to the invention is as follows:
1. The bottom graphene flake is mechanically exfoliated onto silicon oxide. (380 μm doped n-type doped silicon with a dry thermal 300 nm oxide with a polished finish. The process of exfoliation is performed by repeatedly peeling layers of the parent crystal with adhesive tape and firmly pressing the debris onto the wafer's surface. A suitably thin flake is found using an optical microscope.
2. In order to transfer further flakes a transfer procedure is used, which is as follows.
   a. A substrate (can be another silicon wafer) has PMGI (Poly(methyl glutarimide)) spin-coated on one surface with a thickness of −200 nm. The PMGI is then baked on a hot plate at 140° C.
   b. A layer of PMMA (Poly(methyl methacrylate)) is then spin-coated on the surface of the PMGI with a thickness of ˜400 nm and again baked on a hot plate at 140° C., see FIG. 1.
   c. TMDC flakes are exfoliated in the same way as described in step 1. directly onto this polymer stack.
   d. After finding an appropriate flake with an optical microscope, the PMGI layer is dissolved with MF319, leaving the PMMA/flake floating on top of the solvent.
   e. A metal washer is used to ‘fish’ the membrane from the solvent. The structure is inverted and positioned above the target substrate using a modified mask aligner.
   f. The two are carefully brought into contact, after which the PMMA is dissolved in acetone.
   g. The structure can then be annealed in up to 250° C. in a H₂/Ar 10:90 mixture.
3. A further graphene flake is transferred onto the stack in the same way as described in step. 2.
4. Using either optical or e-beam lithography and metal deposition, electrodes contacted to the device; one electrode to each graphene layer, see FIG. 2.

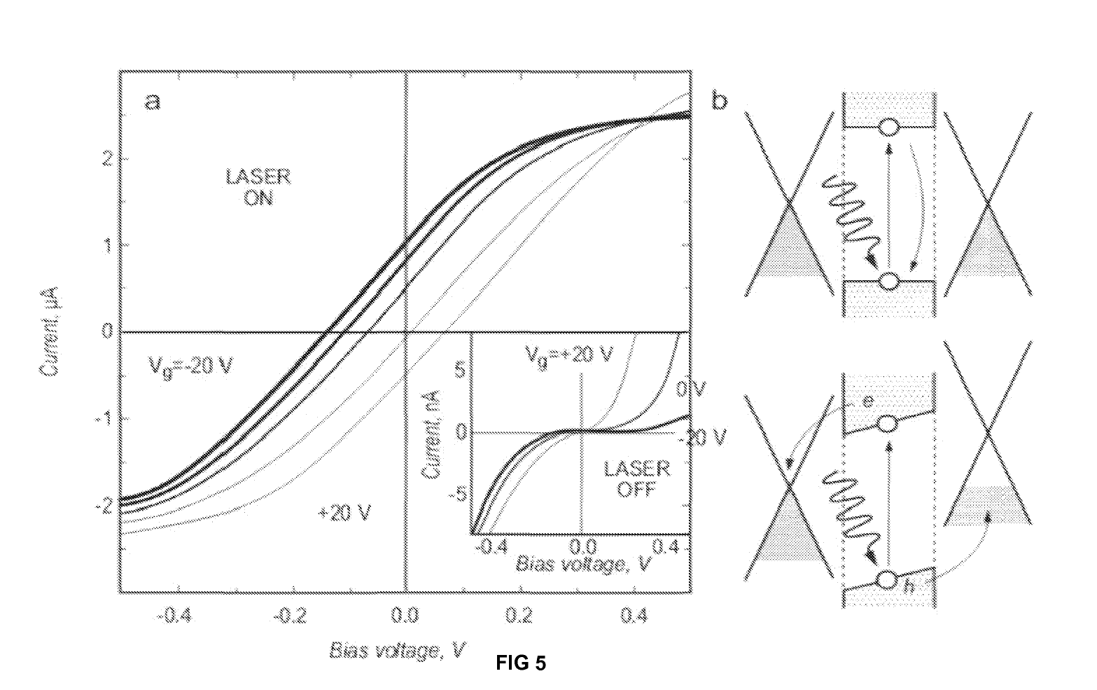

The IV characteristics of our samples strongly depend on illumination, see FIG. 5a. Without illumination, the devices displayed strongly non-linear IV curves (FIG. 5a inset). Comparing this with the main figure, one can see that this was in strong contrast to when they were illuminated: the resistance dropped by more than 3 orders of magnitude and the curves became linear around zero bias. At higher bias (˜±0.2 V) they began to saturate, as the number of available charge carriers in the photoactive region was limited.

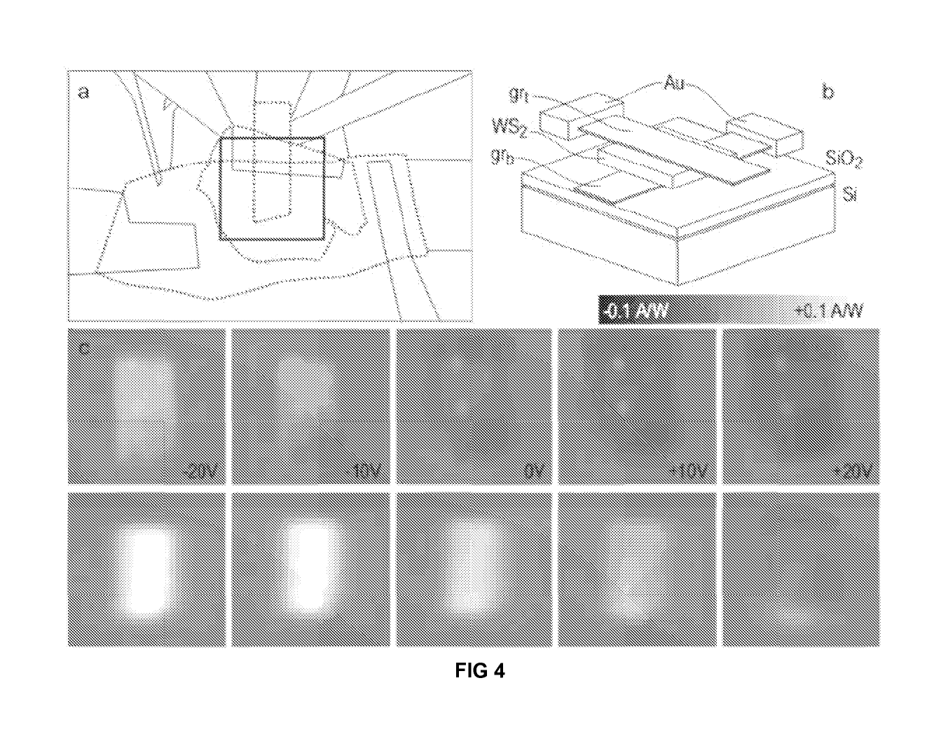

To elucidate further, the photocurrent generated in our devices was mapped by scanning photocurrent microscopy, where a laser spot was scanned over the sample, and the resultant photocurrent displayed as a function of laser spot position. In FIG. 4c one can see that a current is generated only in the region where all three principal layers overlap. With reference to FIG. 5b, we explain the origin of the photocurrent by examining the collective band diagram. In the ideal case the structure is symmetric (FIG. 5b top) and the electrons/holes generated in WS₂ (by absorption of a photon with sufficient energy) will have no preferred diffusion direction and hence no net photocurrent is measured. However, in the presence of a built-in electric field (FIG. 5b bottom) across the WS₂ (either due to a difference in the initial doping between the graphene sheets or by gating), the e-h pairs will be separated and a photocurrent measured.

The effect was investigated by taking photocurrent maps at different gate voltages V_{g}, see FIG. 4c. Immediately after fabrication (which involves the annealing stage), the devices showed a minimum in the integrated photocurrent close to zero gate voltage (FIG. 1C, upper panels, the same can be seen in FIG. 5a). For any finite V_{g} (either positive or negative) the photocurrent increased proportionally to V_{g} but began to saturate at ˜±20 V, again due to the finite number of generated charge carriers. After leaving a non-encapsulated sample in a humid atmosphere for 1 day the photocurrent maps were retaken (FIG. 4c, bottom panels). The photocurrent at zero gate voltage became finite (positive) and the response with gate voltage was shifted by ˜20 V. The effect is also seen in FIG. 5a where the intercept of the IV curves is shifted due to movement of the chemical potential in graphene. In general our devices also showed a strong gate dependence without illumination, which allows them to be used as tunnelling transistors. The highest measured ON/OFF ratio (highest to lowest current modulation) for our devices was 10⁶.

The photocurrent observed in these devices is surprisingly strong for only a few atomic layers of TMDC, but this strong light-matter interaction can be understood from the nature of the electronic states in this material. Ab initio calculations were performed for the DOS and the joint density of states, JDOS, of three single layer semiconducting TMDC: WS₂, WSe₂, and MoS₂. It is clear that in the visible range there are strong peaks, associated with van Hove singularities, in the DOS that lead to enhanced light absorption, and importantly this is a feature that is universal to TMDCs. These van Hove singularities come from the nature of the electronic wave functions: while the valence band is essentially composed of states coming from the d orbitals of the transition metal (TM), the conduction band is characterized by a linear superposition of d orbitals of the TM and p orbitals of the chalcogen atoms. The p orbitals have a localized nature and are also responsible for the a bands which in turn are responsible for the structural stability of these materials (analogous to what happens in graphene). The localized character of the electronic bands (that is, the large effective mass of the carriers) leads to the peaks, i.e., van Hove singularities, in the DOS which are responsible for the enhanced photo-responsivity of these materials from the nanoscopic down to atomic scale. A direct measure of the effect of the van Hove singularities in the optical response of TMDC is given by the JDOS, defined as:

$$JDOS ( E ) = \frac{1}{4 {π}^{3}} \int {d}^{3} k δ ( {E}_{V , k} - {E}_{C , k} - E )$$

where V and C are the valence and conduction bands. the JDOS is a direct measure of the so-called joint critical points, that is, the van Hove singularities in the Brillouin zone around which a photon of energy, hω−E_{c}−Eᵥ, is very effective in inducing electronic transitions over a relatively large region in momentum space. The large contribution to the transition probability for joint critical points gives rise to the structure observed in the frequency dependence of the optical properties of the TMDC. Thus, the photocurrent, I(ω), at some light frequency ω is proportional to JDOS(). There is a sharp rise in the photo-absorption in the JDOS(E) in the visible range of all TMDC studied. In order to further confirm that our results are not dependent on the thickness of the TMDC, we have shown that the DOS and JDOS for bulk (3D) semiconducting TMDCs. The presence of sharp peaks in the DOS and the sharp rise of the JDOS is comparable with the values found for a single layer. Hence, the strong light-mater interactions in semiconducting TMDCs is not a unique feature of the bulk material and it can be extended to monolayers.

The effect discussed here has a similar, albeit with a different physical origin, to the strong Raman absorption in 1D semiconducting carbon nanotubes. In that case, the 1D nature of the material leads to 1/\sqrt{E} singularities in the DOS at the top (bottom) of the valence (conduction) bands, leading also to strong light-matter response.

We have also computed the work function, φ, for the semiconducting TMDCs studied here. We find that the work functions vary considerably depending on the transition metal used (for monolayer, φ_{WS}_{₂}˜2 eV, φ_{WSe}_{₂}˜1.45 eV, φ_{MoS}_{₂}˜2.6 eV) and their thickness (for bulk, φ_{WS}_{₂}˜1.5 eV, φ_{WSe}_{₂}˜1.2 eV, φ_{MoS}_{₂}˜1.98 eV). Notice that since we are using graphene as an transparent electrode (φ_{G}˜4.5 eV), these differences in work function have a direct impact in the device performance.

We also investigated the performance of our prototype light harvesting devices. For power generation, an important parameter is the extrinsic quantum efficiency (EQE), defined as the ratio of the number of charge carriers generated to the number of incident photons. This can be expressed in terms of the photocurrent I, incident power per unit area P and excitation wavelength λ by

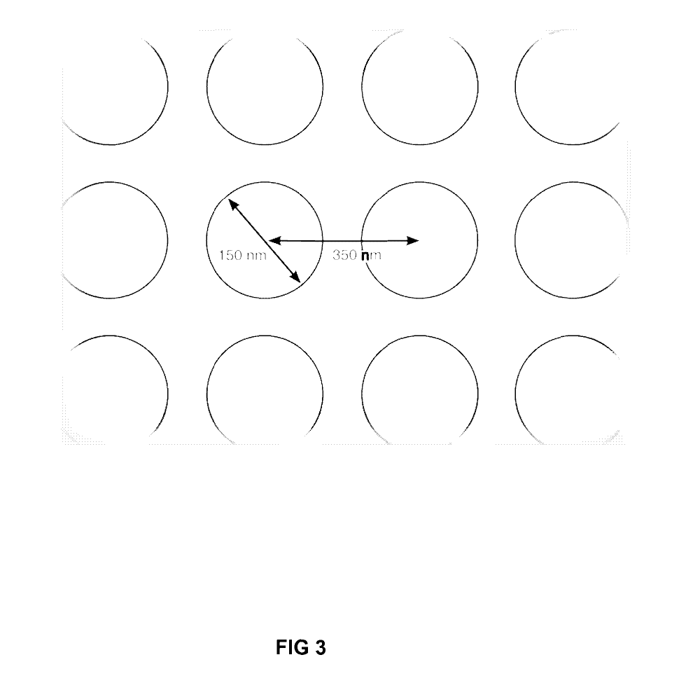

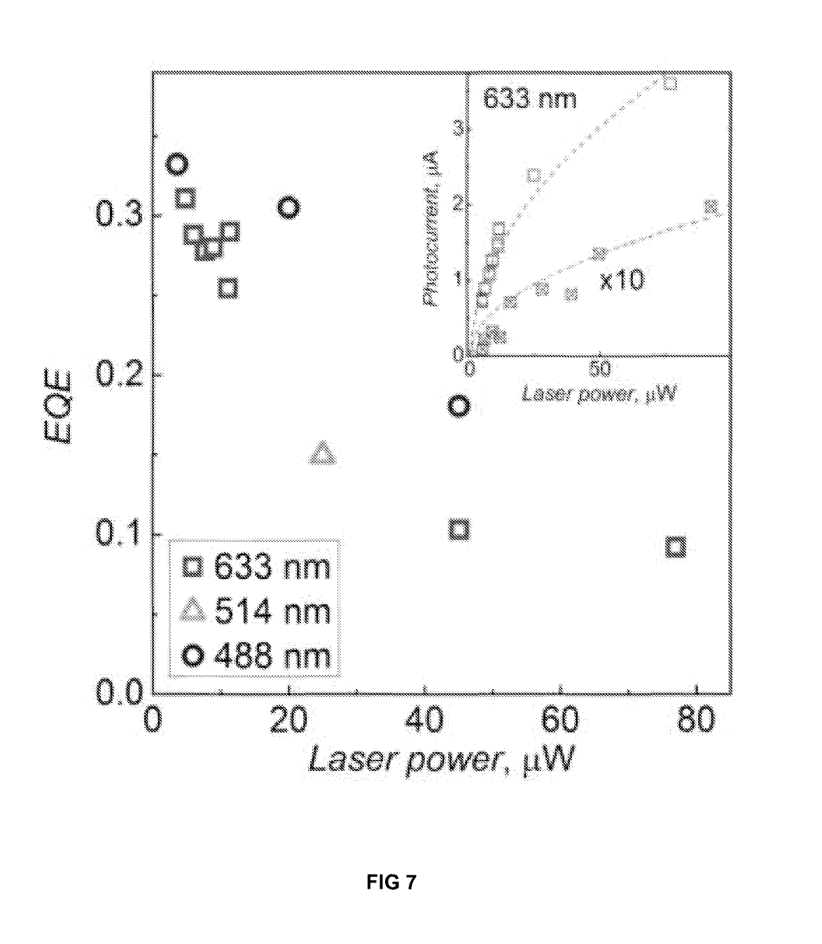

EQE=((h*c)/(e*λ))*(I/P)

where h is the Planck constant, c the speed of light in vacuum and e the electron charge. FIG. 3 shows the effect on the IV characteristics, of irradiance with different intensities. Again, all measured IV curves were linear in the low bias regime and with slopes dependent on the illumination intensity. Using the relation for EQE we calculate the efficiency, shown in FIG. 7, where the data were collected for several wavelengths at zero bias and V_{g}=−40 V. The extrinsic quantum efficiency did not appear to be dependent on wavelength, as expected from the approximately constant optical absorption, over this range. It is likely that the decrease in quantum efficiency with increasing power is due to screening of the built-in electric field by the excited electrons in the conduction band of WS₂. In real devices it is likely that either a thicker WS₂ layer be used or a multiple structures stacked upon each other in order that all incident light is absorbed within the device, pushing EQE even higher.

### CONCLUSIONS

Here we have shown that the fabrication of graphene-WS₂ hybrid devices allows the production of prototypical efficient solar cells. We are able to reach an extrinsic quantum efficiency of 30% which is expected to be higher under lower intensity illumination (e.g. solar radiation) and by optimizing the device design. The photocurrent generated was seen to be almost independent of wavelength from 488 to 633 nm. The same device can be used as a transistor which has ON/OFF ratios exceeding 10⁶. The use of various TMDC as well as their combinations would allow one to create photovoltaic devices with sensitivity in the predetermined spectral range, suitable for large scale production. Devices made from micromechanically cleaved and CVD graphene demonstrate very similar behaviour.

### Methods

Graphene and thin graphite flakes were produced by micromechanical exfoliation of graphite (graphite source). We used single crystal WS₂ supplied in powder form by Sigma-Aldrich. Despite an average crystal size of only 2 μm it is possible to find crystals up to 50 μm that could be exfoliated as well.

Recent progress has led to relatively facile fabrication of graphene hybrid devices with a large degree of versatility. The method allows flakes of layered materials to be transferred to the surfaces of one another with a high degree of accuracy and cleanliness. In this way stacks of different materials can be created with precise control over the constituents of the new hybrid material.

We have used a so-called ‘dry’ transfer technique to create these structures. This technique involves the mechanical exfoliation of the required flakes onto a dual layer polymer stack (PMGI+PMMA). The bottom polymer (PMGI) layer can be selectively dissolved and the resulting membrane inverted and positioned above the target flake—the initial bottom flake was instead cleaved onto a Si/SiO₂ wafer (290 nm oxide). After each transfer the top polymer layer (PMMA) was dissolved and annealed thoroughly in a gaseous mixture of H₂/Ar (10:90) at 300° C. before the subsequent transfer of the next flake. In this way stacks with an arbitrary number of layers can be produced. Once the required flake stack had been fabricated, electrical contact was made via standard photolithographic processing and e-beam evaporation of a Cr adhesion layer (5 nm) and Au (50 nm) and placed in a package for measurements. In order to make scanning photocurrent microscopy measurements we utilize a WiTEC scanning Raman setup. The sample was placed onto a piezoelectric stage with laser light incident from above. The laser was focussed by a ×100 microscope objective with a laser spot size is diffraction limited (diameter ˜500 nm). The laser spot is scanned over the surface and the resultant current flow between the two graphene electrodes is measured alongside the conventional Raman spectra for each point in the scan

We used chemical vapour deposition (CVD) to fabricate high-quality, large area graphene electrodes. The graphene was grown on 25 μm thick copper (Cu) foil (from Alfa Aesar, item no. 13382). Before graphene deposition, the Cu foils were cleaned with subsequent washes in acetone, DI water and IPA in order to remove both organic and inorganic contamination from the surface. To further improve the CVD graphene quality and increase grain size, the Cu foil was then annealed in a quartz tube for 30 minutes at 1000° C. in a flux of H₂ at 20 sccm and 20 mTorr. Graphene was grown on the Cu surface by adding 40 sccm CH₄ to the gas flow (chamber pressure 600 mTorr) whilst maintaining a temperature of 1000° C. The sample was allowed to cool in a H₂ atmosphere and then removed from the chamber at room temperature. The graphene could then be transferred to a silicon wafer by etching of the Cu foil.

### Device Structure and Photocurrent Mapping

Referring to FIG. 4: The top panel shows an optical micrograph of one of our devices and a schematic cartoon of the device. The shading of the three constituent layers denotes the regions of the respective materials—top and bottom graphene electrodes shown in red and blue, while WS₂ is shown in green. The bottom panel shows photocurrent maps taken before (above) and after (below) the device was stored in a humid atmosphere to change doping. The signal is only seen in the area where all three layers overlap. The gate voltage at which the total signal switched sign moved ˜20 V after the device was stored in a humid atmosphere for 1 day.

Gate dependent IV characteristics

FIG. 5 shows: IV curves taken at gate voltage values from −20 to +20 V in 10 V steps, as signified by the arrow. The laser illumination energy was 2.54 eV and the power 10 μW. The curves are linear at low bias but saturate at higher bias due to limited available charge carriers. The inset shows the transistor behaviour of the same device over a larger gate voltage range. This particular device exhibited an ON/OFF ratio ˜5×10³.

### Photoresistivity

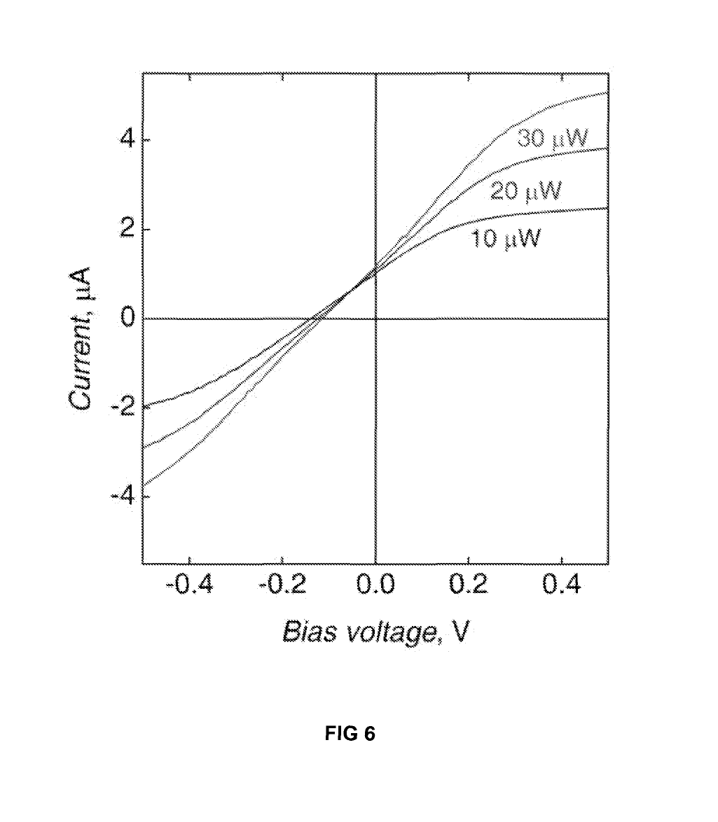

FIG. 6. shows IV characteristics of the device shown under laser illumination of varying intensity. An external bias is applied between the graphene electrodes and the resultant current flow is measured. The resistivity of the device changes only when laser light is incident on the region where all three constituent flakes overlap. Shown are IV curves taken with a 2.54 eV laser set to a total power of 10, 20 and 30 μW and at −20 V_{g}. The inset shows an IV taken without illumination at ±20 V_{g}, the current undergoes a large modulation when the device is positively biased.

### Quantum Efficiency

Referring to FIG. 7: the external quantum efficiency of the devices is the ratio of the number of charge carriers to incident photons. Due to the small variation in optical absorption across this wavelength range the data for different wavelengths collapse onto a single curve. The inset shows (as open squares) the photocurrent measured with a 1.95 eV laser as a function of intensity and follows a sublinear dependence. This results in the largest quantum efficiency values at low intensities.

### Example 2

### Preparation of a Device of the Invention Using Solution Processed Materials

An alternative exemplary method of preparing the devices, cells and heterostructures according to the invention is as follows.
1. Metal electrodes (Cr/Au (5/50 nm) in our case) are patterned onto a substrate (in this case silicon/silicon dioxide).
2. A WS₂ film is prepared as follows.
   a. WS₂ powder is put into a 35% ethanol/water mixture and placed in an ultrasonic bath for 5 days to break up the WS₂ crystals to few layer nanoplatlets which form a suspension.
   b. The suspension is filtered through a cellulose membrane and a film is left, attached to the filter.
   c. By dipping the membrane in water, a thin film (˜50 nm thick) delaminates from the WS₂ film and is left floating on the water's surface.
3. The membrane can be ‘fished’ from the water with the gold patterned substrate so that the WS₂ film covers many metal electrodes.
4. CVD graphene can then be transferred as previously described to form the top, transparent electrode.
5. At each overlap point of the metal/WS₂ film/graphene a device is formed. The size of the devices are limited by the size of the substrate and cellulose membrane not by the active materials.

### Example 3

### Preparation of a Flexible Device

A device as prepared in Example 1 was transferred to a PET (poly(ethylene terephthalate)) substrate and subjected to strain. As the device was put under strain, it's performance as a transistor was measured and it was found that there was no change of the current with a strain of up to about 5%. It was also shown that it is still possible to modulate the current when the device is under strain.

After it was subjected to strain, the photovoltaic properties of the device were tested as for the Si/SiO₂ device described above.

The inset of FIG. 7 shows the photocurrent of the flexible device (inset, as crossed squares) after it has been placed under strain measured with a 1.95 eV laser as a function of intensity and follows a sublinear dependence.

In general, the EQE in our devices on Si/SiO₂ substrate is somewhat higher in comparison with the flexible PET devices due to multiple reflections in SiO₂ which effectively works as a cavity and increases the fraction of light adsorbed in WS₂.

### Example 4

### Preparation of a Graphene/MoS₂/Graphene Device

The results described above for WS₂ devices apply universally to all the transition metal dichalcogenides. We have also shown that a similar behaviour was observed with MoS₂. The devices were fabricated in the same fashion as described in Example 1. To summarise, the devices consist of a tri-layer structure comprising a TMDC flake sandwiched between two electrically isolated graphene layers which act as transparent electrodes. The device sits on an oxidised silicon wafer with the doped silicon acting as a gate electrode. The electric field across the semiconducting region can be altered by applying a voltage between the bottom graphene layer and the doped silicon back gate. The efficiency of our devices fabricated with MoS₂ was found to be lower than for WS₂. This is unexpected from the calculated DOS which are similar for all the TMDCs but it is speculated that a higher level of impurity atoms such as rhenium present in the MoS2 lattice could be responsible due to creation of impurity states in the band gap which increase the rate of recombination.

### Example 5

### Preparation and Photovoltaic Ability of Devices Incorporating Gold Nanostructures

Two devices which incorporate a gold nanostructure were prepared:

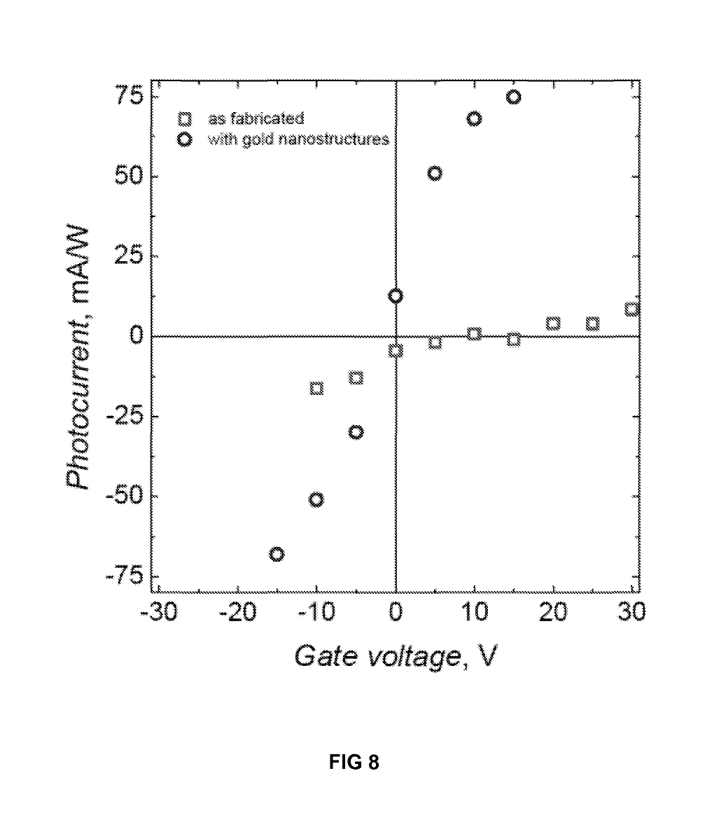

A) A 1 nm thick gold film was thermally evaporated onto a pre-existing graphene/WS₂/graphene device which had previously been seen to exhibit a photovoltaic signal (the device of Example 1). The nanostructures in this case are self-forming as the gold (in the form of Cr/Au (5/50 nm)) does not make a continuous layer but instead forms islands. The signal was seen to increase by a factor of up to 15 following this procedure (FIG. 8).

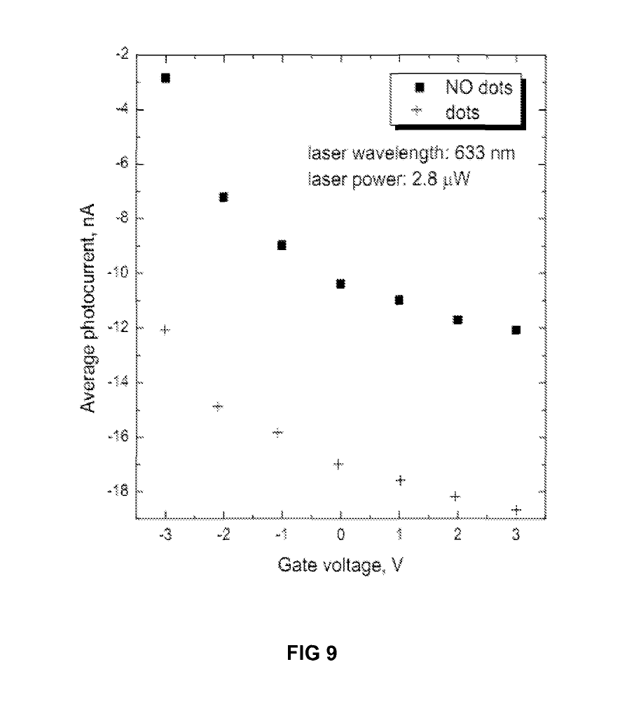

B) A second device type was made (according to the method described in Example 1) in which the photoactive part of the device had two regions: one area where nanostructures were fabricated and one without. The structures are patterned using lithographic techniques. In this case the gold (in the form of Cr/Au (5/50 nm)) dots (disks) have a diameter of 150 nm and a pitch of 350 nm. The average photocurrent was greatly enhanced for the region with the gold dots (disks) compared to the region without the gold dots (FIG. 9)

1. A photovoltaic cell comprising a two-dimensional graphene heterostructure.

2. A photovoltaic cell as claimed in claim 1, wherein the graphene heterostructure comprises two graphene two-dimensional crystals within tunnelling proximity of each other.

3. A photovoltaic cell as claimed in claim 2, wherein the cell further comprises a means of creating an electric field between the graphene crystals.

4. A photovoltaic cell as claimed in claim 2 or claim 3, wherein the heterostructure further comprises a transition metal dichalcogenide (TMDC).

5. A photovoltaic cell as claimed in claim 1, in which the cell has a light harvesting portion which comprises at least the following layers:
a first electrode layer which comprises graphene or modified graphene (e.g. doped graphene);
one or more layers comprising a transition metal dichalcogenide (TMDC); and
a second electrode layer;
wherein the layers are stacked sequentially to form a laminate structure and the or each layer of transition metal dichalcogenide is situated between the first and the second electrode layer and the or each transition metal dichalcogenide layer is in electrical contact with both electrodes.

6. A photovoltaic cell as claimed in claim 5, wherein the first electrode layer, the TMDC layer and the second electrode layer each comprise one or more two-dimensional crystals.

7. A photovoltaic cell as claimed in claim 5 or claim 6, wherein the second electrode layer comprises graphene or modified graphene.

8. A photovoltaic cell as claimed in any one of claims 5 to 7 which further comprises a gate electrode.

9. A photovoltaic cell as claimed in any one of claims 5 to 8 in which one of the electrode layers comprises graphene and the other comprises graphene which has been doped with a dopant which changes the work function of graphene.

10. A photovoltaic cell as claimed in claim 9, wherein the dopant is not chemically bonded to graphene.

11. A photovoltaic cell as claimed in any one of claims 5 to 10, wherein the only active layers the cell contains are the first and second electrode layers and the layer comprising the transition metal dichalcogenide.

12. A photovoltaic cell as claimed in any one of claims 5 to 11, wherein the transition metal dichalcogenide is a compound of one or more of Mo, Ta and W with one or more of S, Se and Te.

13. A photovoltaic cell as claimed in claim 12, wherein the transition metal dichalcogenide is WS₂ or MoS₂.

14. A photovoltaic cell as claimed in any one of claims 5 to 13, wherein the first electrode layer comprises graphene with metal nanostructures on its surface.

15. A photovoltaic cell as claimed in claim 14, in which the metal nanostructures comprise Au.

16. A heterostructure comprising:
a first layer which comprises graphene or modified graphene (e.g. doped graphene);
one or more layers comprising WS₂;
a second layer which comprises graphene or modified graphene (e.g. doped graphene);
wherein the layers are stacked sequentially to form a laminate structure and the or each layer of WS₂ is situated between the first and the second graphene layer.

17. A method of making a heterostructure according to claim 16, the method comprising:
suspending a transition metal dichalcogenide (e.g. WS₂) in a liquid; and
depositing the transition metal dichalcogenide onto a surface to form a thin film.

18. A method according to claim 17, wherein the method further comprises:
subjecting the suspension of the transition metal dichalcogenide in the liquid to ultrasound.

19. A method according to claim 17 or 18, wherein the method further comprises:
using a centrifuge on the suspension to remove any aggregated transition metal dichalcogenide.

20. A use of a two dimensional graphene heterostructure in a photovoltaic cell or device.
